(19) United States
(12) Patent Application Publication
(10) Pub. No.: US 2022/0390524 A1
(43) Pub. Date: Dec. 8, 2022

(54) STORAGE BATTERY STATE ESTIMATION DEVICE AND STORAGE BATTERY STATE ESTIMATION METHOD

(71) Applicant: Mitsubishi Electric Corporation, Tokyo (JP)

(72) Inventor: Tomoki TAKEGAMI, Tokyo (JP)

(73) Assignee: Mitsubishi Electric Corporation, Tokyo (JP)

(21) Appl. No.: 17/776,595

(22) PCT Filed: Feb. 25, 2020
(86) PCT No.: PCT/JP2020/007321

§ 371 Date: May 13, 2022

(51) Int. Cl. G01R 31/396; G01R 31/367; G01R 31/3835

(52) U.S. Cl. CPC G01R 31/396; G01R 31/367; G01R 31/3835

(57) ABSTRACT

To provide a storage battery state estimation device that can accurately perform deterioration diagnosis even when there is no characteristic information of a storage battery.

The storage battery state estimation device includes: a baseline function estimation unit for separating a data point sequence including a capacity and differential voltage of a storage battery into a baseline point sequence and a peak point sequence, and estimating a baseline function on the basis of the baseline point sequence; a peak function estimation unit for estimating a peak function on the basis of the peak point sequence; a model function estimation unit for estimating a model function on the basis of the baseline function and the peak function; an error peak detection unit for detecting presence or absence of an error peak.

### TECHNICAL FIELD

The present disclosure relates to a storage battery state estimation device and a storage battery state estimation method.

### BACKGROUND ART

In order to reduce the burden on the environment, electrically driven vehicles such as electric vehicles (EVs), hybrid electric vehicles (HEVs), and plug-in hybrid vehicles (PKVs) have been put into practical use. Further, development of electrically driven aircrafts and the like is also in progress. In addition, stationary-installation-type power storage systems for utilizing renewable energy is also prevailing.

In such equipment, storage batteries such as lithium ion batteries are used. With respect to the storage batteries, it is known that deterioration advances in association with use, resulting in decreased performance. Therefore, for understanding the replacement time of a storage battery and life prediction thereof, it is necessary to perform deterioration diagnosis for the storage battery. As one of deterioration diagnosis methods for a storage battery, there is a non-destructive deterioration diagnosis method that uses measurement values of current, voltage, and the like of the storage battery.

As a conventional non-destructive deterioration diagnosis method, a deterioration diagnosis method that uses differential voltage obtained through differentiation of voltage of the storage battery with respect to the quantity of electricity has been known. This deterioration diagnosis method uses a fact that the voltage of a storage battery is represented by synthesis of respective potentials of a positive electrode and a negative electrode. The peak shape, the peak-to-peak distance, and the like of a differential potential curve of each of the positive electrode and the negative electrode change in accordance with use of the storage battery. This deterioration diagnosis method performs deterioration diagnosis for a storage battery by using this change in the differential potential curve.

For example, as a conventional deterioration diagnosis method, the following method has been disclosed. First, a differential potential curve obtained from electric characteristics of the positive electrode material and the negative electrode material of a storage battery is obtained in advance. Next, a fitting function that fits this differential potential curve and parameters of the fitting function are obtained by calculation. Lastly, on the basis of variation of parameters of the fitting function calculated from peak positions, peak heights, peak widths, and the like in the differential potential curve obtained from actually measured values of the storage battery in use, deterioration diagnosis is performed (see Patent Document 1, for example).

As another deterioration diagnosis method, the following method has been disclosed. An open circuit voltage (OCV) curve during charge or during discharge of a storage battery in an. initial state is measured in advance. Then, on. the basis of comparison between an OCV curve of the storage battery in use and the OCV curve measured in advance, deterioration diagnosis is performed (see Patent Document 2, for example).

### CITATION LIST

### Patent Document

Patent Document 1: Japanese Patent No. 6123344

Patent Document 2: Japanese Laid-Open Patent Publication No. 2015-230193

### SUMMARY OF THE INVENTION

### Problems to be Solved by the Invention

Prevalence of equipment using a storage battery brings about a large number of used storage batteries. From the viewpoint of resource saving, in order to promote reuse of such a used storage battery, it is necessary to perform deterioration diagnosis for the used storage battery. In a conventional storage battery deterioration diagnosis method, it is necessary to obtain in advance characteristic information such as a differential potential curve obtained from electric characteristics of the positive electrode material and the negative electrode material of a storage battery, an OCV curve in an initial state, and the like. However, in a used storage battery deterioration diagnosis, various storage batteries manufactured by different companies are to be diagnosed. Therefore, it is difficult to obtain in advance characteristic information such as material characteristics, an OCV curve, and the like of various storage batteries.

The present disclosure has been made in order to solve the problems as described above. An object of the present disclosure is to provide a storage battery state estimation device that can accurately perform deterioration diagnosis even when there is no characteristic information of the storage battery to be diagnosed.

### Solution to the Problems

A storage battery state estimation device of the present disclosure includes: a data point sequence generation unit for, on the basis of time-series data of current and voltage of a storage battery, generating a data point sequence including a capacity of the storage battery and differential voltage obtained through differentiation of the voltage with respect to the capacity, or a data point sequence including the voltage of the storage battery and a differential capacity obtained through differentiation of the capacity with respect to the voltage; a baseline function estimation unit for separating the data point sequence into a baseline point sequence and a peak point sequence, estimating a baseline function on the basis of the baseline point sequence, and estimating a parameter, of the baseline function, that minimizes an error between the baseline point sequence and the baseline function; a peak function estimation unit for detecting a peak on the basis of the peak point sequence, estimating a peak function on the basis of the peak point sequence, and estimating a parameter, of the peak function, that minimizes an error between the peak point sequence and the peak function; a model function estimation unit for estimating a model function on the basis of the baseline function, the peak function, the parameter of the baseline function, and the parameter of the peak function, estimating a parameter, of the model function, that minimizes an error between the data point sequence and the model function, and generating an error point sequence including the error between the data point sequence and the mode1 function; an error peak detection unit for detecting presence or absence of an error peak on the basis of the error point sequence, estimating an error peak function on the basis of the error point sequence when the error peak has been detected, and estimating a parameter, of the error peak function, that minimizes an error between the error point sequence and the error peak function; and an electrode model function estimation unit for, when the error peak has not been detected by the error peak detection unit, separating the model function into a positive electrode model function and a negative electrode model function, to perform estimation thereof.

### Effect of the Invention

The storage battery state estimation device of the present disclosure includes: the model function estimation unit for estimating a model function on the basis of the baseline function, the peak function, the parameter of the baseline function, and the parameter of the peak function, estimating a parameter, of the model function, that minimizes an error between the data point sequence and the model function, and generating an error point sequence including the error between the data point sequence, and the model function; the error peak detection unit for detecting presence or absence of an error peak on the basis of the error point sequence, estimating an error peak function on the basis of the error point sequence when the error peak has been detected, and estimating a parameter, of the error peak function, that minimizes an error between the error point sequence and the error peak function; and the electrode model function estimation for, when the error peak has not been detected by the error peak detection unit, separating the model function into a positive electrode model function and a negative electrode model function, to perform estimation thereof. Therefore, the storage battery state estimation device of the present disclosure can accurately perform deterioration diagnosis even when there is no characteristic information of the storage battery to be diagnosed.

### BRIEF DESCRIPTION OF THE DRAWINGS

FIG. 1 is a configuration diagram of a storage battery state estimation device according to embodiment 1.

FIG. 2 is a flow chart showing a process performed by the storage battery state estimation device of embodiment 1.

FIG. 3 is a flow chart showing a process performed by a function generation unit of embodiment 1.

FIG. 4 is a characteristic diagram of a storage battery in embodiment 1.

FIG. 5 is a characteristic diagram showing a potential curve and a differential potential curve of a positive electrode in embodiment 1.

FIG. 6 is a characteristic diagram showing a potential curve and a differential potential curve of a negative electrode in embodiment 1.

FIG. 7 shows characteristic diagrams showing a potential curve and a differential potential curve of a storage battery in embodiment 1.

FIG. 8 shows characteristic diagrams showing a differential potential curve and a difference peak of a storage battery in embodiment 1.

FIG. 9 shows characteristic diagrams showing a difference peak and a differential voltage of a storage battery in embodiment 1.

FIG. 10 shows characteristic diagrams of a storage battery estimated in the storage battery state estimation device of embodiment 1.

FIG. 11 shows characteristic diagrams of a storage battery estimated in the storage battery state estimation device of embodiment 1.

FIG. 12 shows characteristic diagrams of a storage battery estimated in the storage battery state estimation device of embodiment 1.

FIG. 13 shows characteristic diagrams of a storage battery estimated in the storage battery state estimation device of embodiment 1.

FIG. 14 is a schematic diagram showing an example of hardware of the storage battery state estimation device of embodiment 1.

### DESCRIPTION OF EMBODIMENTS

Hereinafter, a storage battery state estimation device according to an embodiment, for implementing the present disclosure will be described in detail with reference to the drawings. In the drawings, the same or corresponding parts are denoted by the same reference characters.

### Embodiment 1

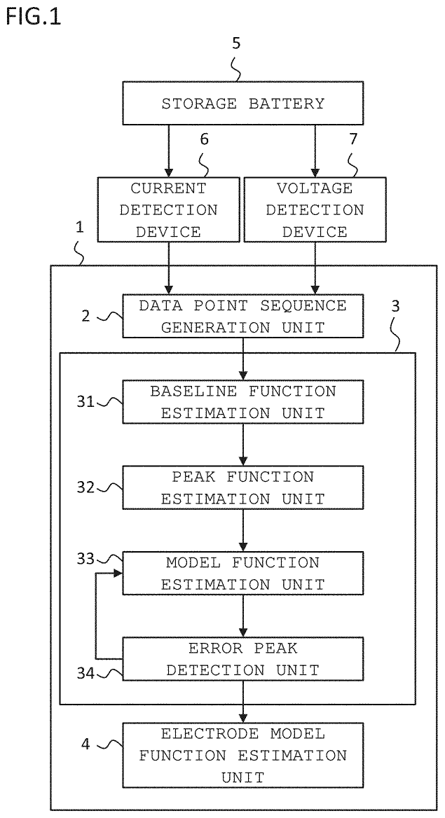

FIG. 1 is a configuration diagram showing a storage battery state estimation device according to embodiment 1. In the present embodiment, description is given assuming that the storage battery to be diagnosed is a single cell lithium ion battery. In a lithium ion battery to be diagnosed, an NMC (Ni—Mn—Co)-based material is used in the positive electrode and graphite is used in the negative electrode. However, the storage battery to be diagnosed encompasses a general storage battery that has a positive electrode and a negative electrode and that can be charged and discharged. The storage battery to be diagnosed may be a lead storage battery, a nickel hydrogen storage battery, an all-solid storage battery, or the like, other than a lithium ion battery. The storage battery to be diagnosed may be a storage battery module in which a plurality of cells are connected in. series, or a storage battery module in which a plurality of cells are connected in parallel, other than a single cell storage battery. Further, the storage battery to be diagnosed may be a storage battery module configured as a combination of serial connection and parallel connection of a plurality of cells.

As shown in FIG. 1, a storage battery state estimation device 1 of the present embodiment includes a data point sequence generation unit 2, a function generation unit 3, and an electrode model function estimation unit 4. The function generation unit 3 includes a baseline function estimation unit 31, a peak function estimation unit 32, a model function estimation unit 33, and an error peak detection unit 34. A current detection device 6 and a voltage detection device 7 are connected to a storage battery 5 to be diagnosed. A current value of the storage battery 5 detected by the current detection device 6 and a voltage value of the storage battery 5 detected by the voltage detection device 7 are inputted to the data point sequence generation unit 2.

A hardware configuration of the storage battery state estimation device 1 of the present embodiment is briefly described. The storage battery state estimation device 1 is implemented by a controller. The controller includes a processor and a memory. Functions of components, i.e., the data point sequence generation unit 2, the baseline function estimation unit 31, the peak function estimation unit 32, the model function estimation unit 33, the error peak detection unit 34, and the electrode model function estimation unit 4, which form the storage battery state estimation device 1, are realized by software, firmware, or a combination of these. Software and firmware are described as programs and are stored in the memory. The processor reads out a program stored in the memory and executes the program, thereby realizing the functions of the components of the storage battery state estimation device 1.

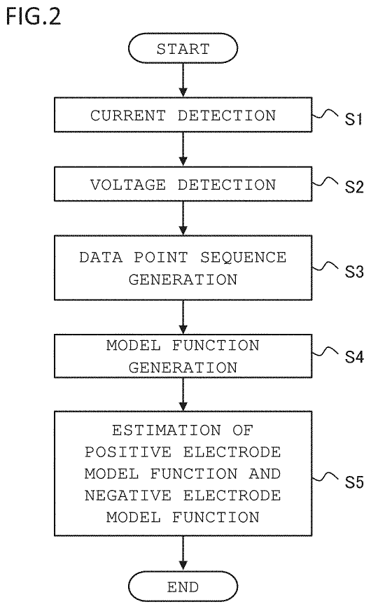

Operation of the storage battery state estimation device 1 is described. FIG. 2 is a flow chart showing the outline of a process performed by the storage battery state estimation device 1. In step S1, current of the storage battery 5 is detected by the current detection device 6. In step S2, voltage of the storage battery 5 is detected by the voltage detection device 7. The current detected in step S1 and the voltage detected in step S2 are inputted to the data point sequence generation unit 2. In step S3, the data point sequence generation unit 2 generates a data point sequence on the basis of the inputted current and voltage. In step S4, the function generation unit 3 generates a model function of the storage battery 5 on the basis of the data point sequence generated by the data point sequence generation unit 2, and executes calculation according to an optimization method to estimate a parameter, of the model function, that minimizes an error between the data point sequence and the model function. Lastly, in step S5, the electrode model function estimation unit 4 estimates a positive electrode model function and a negative electrode model function on the basis of the model function generated by the function generation unit 3.

The current detection device 6 detects current of the storage battery 5 and outputs time-series data of the current value to the data point sequence generation unit 2. The voltage detection device 7 detects voltage of the storage battery 5 and outputs time-series data of the voltage value to the data point sequence generation unit 2. Here, the sampling period of the time-series data is defined as tₛ (seconds).

Next, operation in each component of the storage battery state estimation device 1 of the present embodiment is described in detail.

<Data Point Sequence Generation Unit>

The data point sequence generation unit calculates a data point sequence of a standardized capacity on the basis of an inputted current value I and the sampling period tₛ. In addition, the data point sequence generation unit 2 calculates a data point sequence of a differential voltage on the basis of an inputted voltage value V and the data point sequence of the standardized capacity. Lastly, the data point sequence generation unit 2 generates and outputs a data point sequence formed from the data point sequence of the standardized capacity and the data point sequence of the differential voltage.

The data point sequence generated by the data point sequence generation unit 2 is represented by expression (1).

[Mathematical 1]

{(sₖ, Vₖ′)}ₖ₌₀^{d} (1)

The data point sequence described as above is defined by a general expression such as expression (2).

[Mathematical 2]

{(xₖ, yₖ)}ₖ₌₀^{d}≈{(x₀, y₀), (x₁, y₁), . . . , (x_{d}, y_{d})} (2)

Here, sₖ is a standardized capacity, and is differential voltage. The differential voltage V′ₖ is defined as V′ₖ=dVₖ/dsₖ. k is a sampling parameter. When the time at which obtainment of data is started for diagnosis is defined as 0 seconds, and the sampling time is defined as t seconds, t=tₛ×k is established. The standardized capacity sₖ can he calculated by using expression (3) and expression (4) from capacity qₖ (coulomb).

$$[ Mathematical 3 ]$$

$${q}_{k + 1} = {q}_{k} + {t}_{s} {l}_{k} \qquad ( 3 )$$

$$[ Mathematical 4 ]$$

$${s}_{k} = \frac{{q}_{k}}{{q}_{typ}} \qquad ( 4 )$$

Here, capacity q_{typ} is a standardized full charge capacity, and typically, the rated capacity or the full charge capacity in the initial state of the storage battery to be diagnosed can be used. Vₖ and Iₖ are a voltage value and a current value at the time of sampling parameter k. qₖ is the capacity at the time of sampling parameter k. Standardized capacity sₖ is the ratio of the state of charge (SOC) at the time of sampling parameter k when the standardized full charge capacity is used as a reference. Therefore, standardized capacity sₖ is a value from 0 to 1. By using standardized capacity sₖ, it becomes possible to analyze storage batteries having various rated capacities, on the basis of the same reference. Capacity qₖ may be used instead of standardized capacity sₖ.

As a calculation method for differential voltage dVₖ/dsₖ, since Vₖ and sₖ are discrete data point sequences, approximate differentiation according to a difference method or the like can be used. When differential voltage is calculated by using approximate differentiation, there is a possibility that noise included in the inputted current value I and voltage value V is amplified. In order to suppress this, a low-pass filter may be used in current detection and voltage detection, or the sampling periods of current detection and voltage detection may be adjusted.

The data, point sequence generated in this manner is stored, including data point sequences generated in the past, in a memory inside the storage battery state estimation device 1 or a data server, a cloud, or the like outside the storage battery state estimation device 1.

<Function Generation Unit>

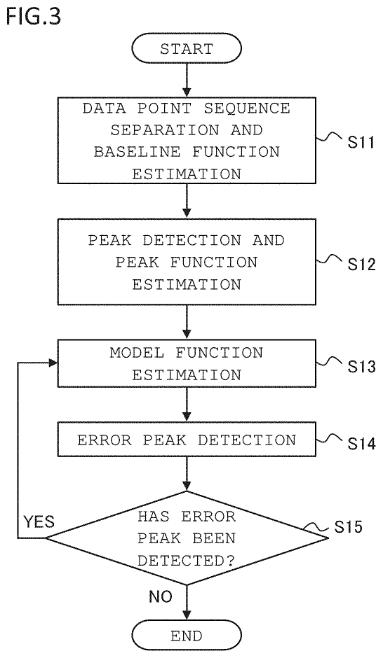

The function generation unit 3 generates a model function on the basis of the data point sequence outputted by the data point sequence generation unit 2. In addition, the function generation unit 3 generates a parameter, of the model function, that minimizes the error between the data point sequence and the model function. Then, the function generation unit 3 outputs the model function and the parameter of the model function. FIG. 3 is a flow chart showing the outline of a process performed by the function generation unit 3. In step S11, the baseline function estimation unit 31 separates the data point sequence into a baseline point sequence and a peak point sequence, and estimates a baseline function with respect to the baseline point sequence. In step S12, the peak function estimation unit 32 detects peaks from the peak point sequence and estimates a peak function with respect to the peak point sequence. In step S13, the model function estimation unit 33 causes the baseline function and the peak function to be superposed with each other, to estimate a model function that corresponds to the data point sequence. Further, in step S13, the model function estimation unit 33 generates an error point sequence that has the error between the model function and the data point sequence as an element. In step S14, the error peak detection unit 34 detects error peaks from the error point sequence generated by the model function estimation unit 33. Further, in step S15, the error peak detection unit 34 determines whether or not any error peak has been detected. In step S15, when no error peak has been detected, the function generation unit 3 outputs the model function and the parameter of the model function, and ends the process. In step S15, when any error peak has been detected, the error peak detection unit 34 estimates an error peak function, and outputs the error peak function to the model function estimation unit 33, and the process returns to step S13. Until no error peak is detected and the process is ended, the loop between step S13 and step S15 is repeated.

Operation of the electrode model function estimation unit 4 will be described later.

Next, operation performed in components of the function generation unit 3 is described in detail.

### <Baseline Function Estimation Unit>

The baseline function estimation unit 31 separates the data point sequence outputted by the data point sequence generation unit 2, into a baseline point sequence and a peak point sequence. Next, the baseline function estimation unit 31 estimates a baseline function by using a later-described method with respect to the baseline point sequence. The baseline function estimation unit 31 estimates a parameter, of the baseline function, that minimizes the error between the baseline point sequence and the baseline function. Lastly, the baseline function estimation unit 31 outputs the baseline point sequence, the peak point sequence, the baseline function, and the parameter of the baseline function.

Here, the baseline point sequence and the peak point sequence are represented by expression (5) and expression (6), respectively.

[Mathematical 5]

{(sₖ, V_{b,k}′)}ₖ₌₀^{d} (5)

[Mathematical 6]

{(sₖ, V_{p,k}′)}ₖ₌₀^{d} (6)

At this time, a relationship represented by expression. (7) is established between differential voltage v′ₖ, baseline differential voltage V′_{b,k}, and peak differential voltage V′_{p,k}.

[Mathematical 7]

Vₖ′=V_{b,k}′+V_{p,k}′ (7)

As a method for separating a data point sequence into a baseline point sequence and a peak point sequence, there is a method, for example, in which a convex hull of the data point sequence is formed, and a lower hull of the convex hull, i.e., the line connecting counterclockwise a data point at the left end and a data point at the right end on the peripheral line of the convex hull, is used as a baseline point sequence. Alternatively, as another method, for example, there is a method in which a baseline point sequence and a peak point sequence are separated from each other by using a point sequence obtained by causing a data point sequence to pass through a low-pass filter. This method is based on an interpretation that, in a differential voltage curve, a peak curve represents high frequency components, and a baseline curve represents low frequency components. Thus, the determination method of a baseline point sequence in the baseline function estimation unit 31 is not limited only to the method that uses a lower hull of a convex hull.

As seen from expression (7), the difference between the differential voltage and the baseline differential voltage is the peak differential voltage. The baseline point sequence is represented by expression (3) when subscripts of the data point sequence included in the lower hull are defined as σ₁, σ₂, . . . , σₕ.

[Mathematical 8]

{(s_{σ}_{₁}, V_{σ}_{₁}′)(s_{σ}_{₂}, V_{σ}_{₂}′), . . . , (s_{σ}_{_{c}}, V_{σ}_{ₕ}′)} (8)

Then, baseline differential voltage V′_{b,k} is represented by expression (9).

[Mathematical 9]

V_{b,k}′=fᵢₜₚ₁(sₖ; {(s_{σ}_{₁}, V_{σ}_{₁}′), (s_{σ}_{₂}, V_{σ}_{₂}′), . . . , (s_{σ}_{_{c}}, V_{σ}_{ₕ}′)}) (9)

Here, is a function that. outputs baseline differential voltage at standardized capacity sₖ through piecewise linear interpolation of the baseline point sequence represented by expression (8), i.e , the lower hull.

The baseline function can be expressed as superposition of a plurality of functions. For example, the baseline function can be expressed as a function obtained by superposition. of a peak function, a sigmoid-type function being an integration form thereof, an exponential function, a constant term, and the like. That is, baseline function f_{b} is represented by expression (10) as superposition of element baseline functions f_{b,1}, f_{b,2}, . . . , f_{b,nb}.

[Mathematical 10]

f_{b}(s; θ_{b})=Σᵢ₌₁ⁿ^{_{b}}f_{b,i}(s;θ_{b,i}) (10)

Here, θ_{b} and θ_{b,i} are defined by expression (11) and expression (12), respectively.

[Mathematical 11]

θ_{b}:=[θ_{b,1}^{T}, θ_{b,2}^{T}, . . . , θ_{b,n}_{_{b}}^{T}]^{T} ∈ [symbol] ^{m}^{_{b}} (11)

[Mathematical 12]

θ_{b,i}:=[θ_{b,i1},θ_{b,i2}, . . . , θ_{b,im}_{_{bi}}]^{T} ∈ [symbol] ^{m}^{_{bi}} (12)

θ_{b} is a parameter to be estimated for baseline function f_{b}, and θ_{b,i} is a parameter to be estimated for element baseline function f_{b,i}.

At this time, the parameter estimation problem of the baseline function becomes a problem in which an optimum parameter θ′_{b} is to be obtained by solving expression (13) below. That is, the baseline function estimation unit 31 estimates a parameter, of the baseline function, that minimizes the error between the baseline point sequence and the baseline function. Therefore, the superscript asterisk indicates that this parameter is the optimum parameter estimated by the baseline function estimation unit 31. m_{b} is the total number of parameters to be estimated, and R^{mb} is a set of m_{b}-dimensional real numbers.

$$[ Mathematical 13 ]$$

$${min}_{{θ}_{b} ∈ {ℛ}^{{m}_{b}}} {\sum }_{k = 0}^{d} {( {f}_{b} ( {s}_{k} ; {θ}_{b} ) - {V}_{b , k}^{′} )}^{2} \qquad ( 13 )$$

In order to estimate the optimum parameter θ′_{b} by solving this problem with use of an optimization method, a publicly known non-linear optimization method can be used. For example, the Gauss-Newton method, the Levenberg-Marquardt method, or the like can be used as an optimization method. There may be some information regarding parameters to be estimated, for example, information that a parameter is non-negative, or the like. In such a case, such information may be caused to be included as a constraint condition, whereby the optimization method may be formulated as a non-linear optimization problem with a constraint condition. As an optimization method in this case, a penalty function method, a sequential quadratic programming method, a generalized reduced gradient method. (GRG method), or the like can be used.

It should be noted that the aforementioned optimization methods without a constraint condition and with a constraint condition are examples, and an optimization method such as metaheuristics may be used as another optimization method. Further, optimization methods may be separately used in accordance with the scale (the number of parameters) of the problem and the scale (processing speed, memory amount, and the like) of calculation resources.

The optimization problem formulation method is not limited to expression (13). As a simple example, formulation of the optimization problem may be minimization of the sum of fourth power errors instead of minimization of the sum of square errors as in expression (13), or may be minimization of a weighted sum including a regularization term and the like.

By performing such estimation, the baseline function estimation unit 31 outputs the data point sequence, the peak point sequence, the baseline function, and the parameter of the baseline function.

<Peak Function Estimation Unit>

The peak function estimation unit 32 applies a peak detection technique to the peak point sequence outputted by the baseline function estimation unit 31, and detects peaks. Next, the peak function estimation unit 32 estimates a peak function obtained by superposition of element peak functions corresponding to the detected peaks. Further, using information. regarding each detected peak, such as information of the position of the peak, the height of the peak, and the half-width of the peak, the peak function estimation unit 32 estimates a parameter, of the peak function, that minimizes the error between the peak point sequence and the peak function. Lastly, the peak function estimation unit 32 outputs the peak function, the parameter of the peak function, and the data point sequence, the baseline function, and the parameter of the baseline function received from the baseline function estimation unit 31.

As a peak detection. technique in the peak function estimation unit 32, a publicly known peak detection algorithm may be used. At that time, if reference values for peak detection, such as, For example, reference values of minimum peak height, minimum peak width, and maximum peak width, are set, peak detection can be performed even when noise is included. The peak function fₚ can be represented by expression (14) as superposition of nₚ element peak functions f_{p,1}, f_{p,2}, . . . , p_{p,np}.

[Mathematical 14]

fₚ(s;θₚ)=Σᵢ₌₁ⁿ^{ₚ}f_{p,i}(s;θ_{p,i}) (14)

Here, θₚ and θ_{p,i} are defined by expression (15) and expression (16), respectively.

[Mathematical 15]

θₚ:=[θ_{p,1}^{T}, θ_{p,2}^{T}, . . . , θ_{p,n}_{ₚ}^{T}]^{T} ∈ [symbol] ^{m}^{ₚ} (15)

[Mathematical 16]

θ_{p,i}:=[θ_{p,i1}, θ_{p,i2}, . . . , θ_{p,im}_{ₚᵢ}]^{T} ∈ [symbol] ^{m}^{ₚᵢ} (16)

θₚ is a parameter to he estimated for peak function fₚ, and θ_{p,i} and is a parameter to be estimated for element peak function f_{p,i}.

At this time, the parameter estimation problem of the peak function becomes a problem in which an optimum parameter θ*ₚ is to be obtained by solving expression (17) below. That is, the peak function estimation unit 32 estimates a parameter, of the peak function, that minimizes the error between the peak point sequence and the peak function. Here, the superscript asterisk indicates that this parameter is the optimum parameter estimated by the peak function estimation unit 32, mₚ is the total number of parameters to be estimated, and R^{mp} is a set of mₚ-dimensional real numbers.

$$[ Mathematical 17 ]$$

$${min}_{{θ}_{p} ∈ {ℛ}^{{m}_{p}}} {\sum }_{k = 0}^{d} {( {f}_{p} ( {s}_{k} ; {θ}_{p} ) - {V}_{p , k}^{′} )}^{2} \qquad ( 17 )$$

As element peak function f_{p,i}, a density function that represents a probability distribution such as Gaussian distribution, logistic distribution, or Cauchy distribution, can be used, for example. Alternatively, as an element peak function, a density function that represents a more complicated probability distribution, such as a density function that represents a left-right asymmetric probability distribution, may be used. Of course, the element peak function need not necessarily be a density function, and any function that has a peak as an element peak function can be used. The method for solving this problem is similar to the method described with respect to solving the parameter estimation problem of the baseline function. As initial parameters of θₚ and θ_{p,i} when solving the parameter estimation problem, information regarding each peak, such as information of the position of the peak, the height of the peak, the half-width of the peak, and the like, can be used.

By performing such estimation, the peak function estimation unit 32 outputs the peak function, the parameter of the peak function, and the data point sequence, the baseline function, and the parameter of the baseline function received from the baseline function estimation unit 31.

<Model Function Estimation Unit>

The model function estimation unit 33 receives the baseline function, the parameter of the baseline function, the peak function, the parameter of the peak function, and the data point sequence outputted from the baseline function estimation unit 31 and the peak function estimation unit 32. Then, the model function estimation unit 33 causes the baseline function and the peak function to be superposed with each other, to estimate a model function that corresponds to the data point sequence. In addition, on the basis of the parameter of the baseline function and the parameter of the peak function, the model function estimation unit 33 estimates a parameter, of the model function, that minimizes the error between the estimated model function and the data point sequence. Further, the model function estimation unit 33 generates an error point sequence that has the error between the model function and the data point sequence as an element. Lastly, the model function estimation unit 33 outputs the model function, the parameter of the model function, and the error point sequence.

The error point sequence generated by the model function estimation unit 33 is represented by expression (18).

[Mathematical 18]

{(sₖ, εₖ)}ₖ₌₀^{d} (18)

Here, error εₖ is defined by expression (19) below, as the difference between model function f and the data point sequence.

[Mathematical 19]

εₖ:=f(sₖ;θ)−Vₖ′ (19)

Model function f is given by expression (20) below, as the sum of baseline function f_{b} and peak function fₚ.

[Mathematical 20]

f(s; θ)=f_{b}(s; θ_{b})+fₚ(s;θₚ) (20)

Here, θ is defined by expression (21).

[Mathematical 21]

θ:=[θ_{b}^{T}, θₚ^{T}]^{T} ∈ [symbol] ^{m} (21)

θ is a parameter to be estimated for model function f. At this time, the parameter estimation problem of the model function becomes a problem in which an optimum parameter θ^{#} is to be obtained by solving expression (22) below. That is, the model function estimation unit 33 estimates a parameter, of the model function, that minimizes the error between the model function and the data point. sequence. Here, the superscript number sign indicates that this parameter is the optimum parameter estimated by the model function estimation unit 33. It should be noted that m=m_{b}+mₚ.

$$[ Mathematical 22 ]$$

$${min}_{θ ∈ {ℛ}^{m}} {\sum }_{k = 0}^{d} {( {f}_{} ( {s}_{k} ; θ ) - {V}_{k}^{′} )}^{2} \qquad ( 22 )$$

The method for solving this problem is similar to the method described with respect to solving the parameter estimation problem of the baseline function. In setting of the initial parameter θᵢₙᵢ of the model function, the optimum parameter θ*_{b} of the baseline function and the optimum parameter θ*ₚ of the peak function can be used. That is, the initial parameter θᵢₙᵢ of the model function can be set as in expression (23). When the initial parameter of the model function is set in this manner, it becomes possible to start calculation from a value close to an optimum parameter.

[Mathematical 23]

θᵢₙᵢ=[θ*_{b}^{T}, θ*ₚ^{T}]^{T} (23)

The model function estimation unit 33 estimates the optimum parameter θ^{#} of the model function shown in expression (1) by solving expression (22).

[Mathematical 24]

σ^{#}=[θ_{b}^{#}^{^{T}}, θₚ^{#}^{^{T}}]^{T} ∈ [symbol] ^{m} (24)

Here, θ_{b}^{#} is the optimum parameter of the baseline function estimated by the model function estimation unit 33, and θₚ^{#} is the optimum parameter of the peak function estimated by the model function estimation unit 33. That is, the superscript number sign indicates that this parameter is the optimum parameter estimated by the model function. estimation unit 33.

By performing such estimation, the model function estimation unit 33 outputs the model function, the parameter of he model function, and the error point sequence.

<Error Peak Detection Unit>

The error peak detection unit 34 detects error peaks by applying a peak detection technique to the error point sequence outputted. from the model function estimation unit 33. When any error peak has been detected, the error peak detection unit 34 estimates an error peak function represented by the sum of element error peak functions, by a method similar to that used in the peak function estimation unit 32, with respect to the one or more detected error peaks. Further, the error peak detection unit 34 estimates a parameter, of the error peak function, that minimizes the error between the error peak function and the error point. sequence. Lastly, the error peak detection unit 34 outputs the error peak function and the parameter of the error peak function to the model function estimation unit 33. As described later, when the model function estimation unit 33 has received the error peak function and the parameter of the error peak function from the error peak detection unit 34, the model function estimation unit 33 reconstructs the model function and the parameter of the model function and outputs the resultant model function. and parameter.

It is assumed that this is the j-th time (j is a natural number) the error peak detection unit 34 has received the model function from the model function estimation unit 33. At this time, the j-th order error peak function is represented by expression (25) as superposition of nₚₑ₍ⱼ₎ element error peak functions f^{(j)}_{pe,i}.

[Mathematical 25]

fₚₑ^{(j)}(s;θₚₑ^{(j)})=Σᵢ₌₁ⁿ^{ₚₑ}^{(j)}f_{pe,i}^{(j)}(s;θ_{pe,i}^{(j)}) (25)

Here, θ^{(j)}ₚₑ is defined by expression (26).

[Mathematical 26]

Θₚₑ^{(j)}:=[θ_{pe,1}^{(j)T}, θ_{pe,2}^{(j)T}, . . . θ_{pe,n}_{ₚₑ}₍ⱼ₎^{(j)T}] (26)

θ^{(j)}_{pe,i} is a parameter of the i-th element error peak function of the j-th order error peak function,

When. the error peak detection unit 34 has not detected any error peak, the error peak detection unit 34 outputs the model function and the parameter of the model function at the time point.

<Model Function Estimation Unit>

When the model function estimation unit 33 has received the error peak function and the parameter of the error peak function from the error peak detection unit 34, the model function estimation unit 33 respectively adds the error peak function and the parameter of the error peak function to the model function and the parameter of the model function that have been used up to that time point, thereby reconstructing the model function. Then, using the reconstructed model function, the model function estimation unit 33 estimates a parameter, of the reconstructed model function, that minimizes the error with respect to the data point sequence. Further, the model function estimation unit 33 regenerates an error point, sequence that has the error between the reconstructed model function and the data point sequence as an element.

It is assumed that this is the r-th time (r is a natural number) the model function estimation unit 33 has received the error peak function and the parameter of the error peak function from the error peak detection unit 34. The r-order model function f^{(r)} having been reconstructed r times is represented by expression (27) below.

[Mathematical 27]

f^{(r)}(s;θ^{(r)})=f(s;θ)+θⱼ₌₁^{r}fₚₑ^{(j)}(s;θₚₑ^{(j)}) (27)

Here, θ^{(r)} is defined by expression (28).

[Mathematical 28]

θ^{(r)}:=[θ^{T},θₚₑ^{(1)T},θₚₑ^{(2)T} . . . , θₚₑ^{(r)T}]^{T} (28)

In estimation of the parameter of the r-th-order model function, the initial parameter can be set as expression (29).

[Mathematical 29]

θᵢₙᵢ^{(r)}=[θ^{(r-1#T}, θₚₑ^{(r)*T}]^{T} (29)

Here, θ^{(r)*}ₚₑ is the optimum parameter of the r-th-order error peak function f^{(r)*}ₚₑ estimated by the error peak detection unit 34. θ^{(r-1)#} is the optimum parameter of the r-1-th-order model function f^{(r-1)} estimated by the model function estimation unit 33.

Since the loop is made between the model function estimation unit 33 and the error peak detection unit 34, estimation accuracy of the model function can be improved peak detection failure can be prevented in the function generation unit 3.

When the error peak detection unit 34 having received the regenerated error point sequence does not detect any error peak, the error peak detection unit 34 outputs the model function and the parameter of the model function at that time point.

Next, operation performed in the electrode model function estimation unit 4 is described in detail.

<Electrode Model Function Estimation Unit>

The electrode model function estimation unit 4 separates the model function. generated in the function generation unit 3 into a positive electrode model function and a negative electrode model function to perform estimation thereof, on the basis of at least. one of information regarding the positive electrode potential and the negative electrode potential of a storage battery of the same kind as the storage battery to be diagnosed, and information of a model function of a storage battery of the same kind as the storage battery to be diagnosed. These pieces of information need not necessarily be information regarding the storage battery to be diagnosed itself obtained in advance, and may be general known information regarding a storage battery of the same kind as the storage battery to be diagnosed.

Information regarding the positive electrode potential and the negative electrode potential is, typically, at least one of information regarding the shapes of the potential curves and information regarding the shapes of the differential potential curves of the respective positive electrode and negative electrode.

The information regarding the negative electrode potential is a potential curve of the negative electrode obtained when, for example, with respect to a lithium ion battery using graphite in the negative electrode, the occlusion amount of lithium by the negative electrode is represented by the horizontal axis respect to the potential curve of the negative electrode of such. a lithium ion battery, it is known that in accordance with increase in the occlusion amount of lithium by the negative electrode, the potential varies stepwise with flat regions of the potential. This variation in the potential curve is due to change in the stage structure of the intercalation compound in the graphite layer. A flat region of the potential of the potential curve of the negative electrode is in a two-layer coexistence state in which two stages coexist, and it is considered that the potential varies in association with change in the stage structure. Therefore, with respect to the potential curve of the negative electrode, in a low SOC region, i.e., a region where the occlusion amount of lithium by the negative electrode is not higher than 50%, a plullity of peaks that reflect the process of phase change in which a random stage changes to stage 4, stage 2L, and stage 2 in accordance with increase in the occlusion amount, are observed. In addition, with respect to the potential curve of the negative electrode, in a region where the occlusion amount of lithium by the negative electrode is about 50%, a new peak that reflects phase change to new stage is observed.

Meanwhile, the information regarding the positive electrode potential is the potential curve of the positive electrode obtained when, for example, with respect to a lithium ion. battery using graphite in the negative electrode, the occlusion amount of lithium by the negative electrode is represented by the horizontal axis. The potential curve of the positive electrode of such a lithium ion battery often has a large absolute amount of potential variation when compared with the potential curve of the negative electrode. For example, in the case of the potential curve of a positive electrode based on nickel, manganese, cobalt, NMC (Ni—Mn—Co) as a combination of these, or NCA (Ni—Mn—Al), flat regions of the potential are small in number, peaks due to phase change are gentler and are also small in number in many cases, and the potential is in a gently increasing shape. However, the absolute amount of potential variation in the potential curve of the positive electrode is large when compared with that of the potential curve of the negative electrode.

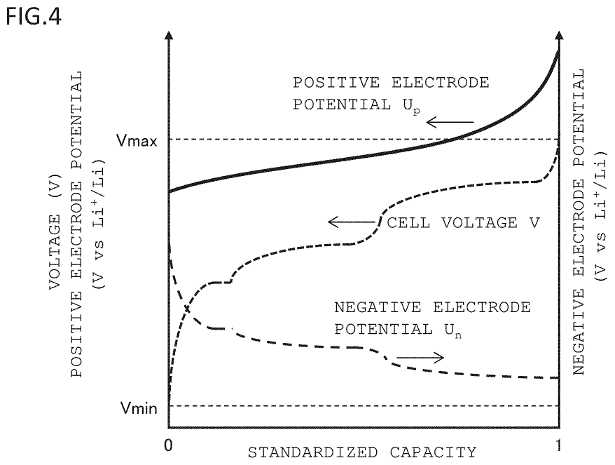

FIG. 4 is a characteristic diagram showing cell voltage V, positive electrode potential Uₚ, and negative electrode potential Uₙ of a lithium ion battery in an initial state. In FIG. 4, the horizontal axis represents standardized capacity when the capacity at full charge is defined as 1, and the vertical axis represents voltage or potential. The left vertical axis represents cell voltage and positive electrode potential, and the right vertical axis represents negative electrode potential. In general, there is a relationship of expression (30) between cell voltage V (V), positive electrode potential Uₚ (V vs Li⁺/Li), and negative electrode potential Uₙ (V vs Li⁺/Li).

[Mathematical 30]

V=Uₚ−Uₙ (30)

Therefore, the shape of the voltage curve of the cell has both features of gentle increase in The positive electrode potential curve and stepwise potential variation in the negative electrode potential curve.

As shown in FIG. 4, in the lithium ion battery in the initial state, the cell voltage when the standardized capacity is 0 (at complete discharge) is determined in accordance with increase in the negative electrode potential, and thus, the positive electrode is still in chargeable state (the lithium amount is less than 1). Conversely, in. the lithium ion battery, the cell voltage when the standardized capacity is 1 (at full charge) is determined in accordance with increase the positive electrode potential, and thus, the negative electrode is a chargeable state (the lithium amount is less than 1). When this is described in terms of the differential voltage curve of the cell, the sharp variation observed where the standardized capacity is near 0 is mainly due to variation in the differential potential curve of the negative electrode, and the sharp variation observed where the standardized capacity is near 1 is due to variation in the differential potential curve of the positive electrode.

Using the feature of the shape of at least one of the voltage curve and the differential voltage curve determined by the electrode material as described above, the relationship between the positive electrode potential and the negative electrode potential in the voltage curve of the storage battery, and the like, the electrode model function estimation unit 4 separates the differential voltage function of the storage battery into a differential potential function of the positive electrode and a differential potential function of the negative electrode, to perform estimation thereof. In other words, the electrode model function estimation unit 4 separates the differential voltage function of the storage battery being a model function, to estimate a differential potential function of the positive electrode being a positive electrode model function, and a differential potential function of the negative electrode being a negative electrode model function.

Next, details of the functions used in the storage battery state estimation device of the present embodiment are described.

Since each function to be estimated is a function obtained through differentiation of voltage or potential, the storage battery state estimation device of the present embodiment uses, as an element function, a function that has a peak when differentiation is performed. As an example of such a function, a logistic function being one of sigmoid-type functions can be used. Expression (31) shows the logistic function.

$$[ Mathematical 31 ]$$

$$F ( x ; k , μ , σ ) = \frac{k}{1 + exp ( - \frac{x - μ}{σ} )} \qquad ( 31 )$$

Here, k is a parameter corresponding to height, μ is a parameter corresponding to position, and σ is a parameter corresponding to gentleness. These parameters are parameters that characterize shape change due to phase change in the potential curve of an electrode.

When expression (31) is differentiated, expression (32) is obtained.

$$[ Mathematical 32 ]$$

$$f ( x ; k , μ , σ ) = \frac{k exp ( - \frac{x - μ}{σ} )}{{σ ( 1 + exp ( - \frac{x - μ}{σ} ) )}^{2}} \qquad ( 32 )$$

Expression (32) is an element peak function representing a peak of a differential potential curve. In general, it is known that the potential curve of an electrode has a stepwise shape due to phase change. Therefore, the potential curve can be represented by the sum of siqmoid-type functions. That is, when the differential potential curve represented by the sum of element peak functions, highly accurate function estimation can be realized.

A positive electrode potential function is represented by expression (33) as an example,

$$[ Mathematical 33 ]$$

$${U}_{p} ( s ) = {c}_{p} + {b}_{p} s + \int F ( s ; {k}_{p , 0} , {μ}_{p , 0} , {σ}_{p , 0} ) ds + {\sum }_{i = 1}^{{m}_{p}} F ( s ; {k}_{p , i} , {μ}_{p , i} , {σ}_{p , i} ) = \\ {c}_{p} + {b}_{p} s + {k}_{p , 0} ( s + {σ}_{p , 0} log ( 1 + exp ( - \frac{s - {μ}_{p , 0}}{{σ}_{p , 0}} ) ) ) + {\sum }_{i = 1}^{{m}_{p}} \frac{{k}_{p , i}}{1 + exp ( - \frac{s - {μ}_{p , i}}{{σ}_{p , i}} )} \qquad ( 33 )$$

Here, cₚ is a constant term, and bₚs is a linear term. The differential potential function of the positive electrode is represented by expression (34) obtained through differentiation of the above expression with respect to s.

$$[ Mathematical 34 ]$$

$$\frac{{dU}_{p} ( s )}{ds} = {b}_{p} + \frac{{k}_{p , 0}}{1 + exp ( - \frac{s - {μ}_{p , 0}}{{σ}_{p , 0}} )} + {\sum }_{i = 1}^{{m}_{p}} \frac{{k}_{p , i} exp ( - \frac{s - {μ}_{p , i}}{{σ}_{p , i}} )}{{( 1 + exp ( - \frac{s - {μ}_{p , i}}{{σ}_{p , i}} ) )}^{2}} \qquad ( 34 )$$

Meanwhile, a negative electrode potential function is represented by expression (35) as an example.

$$[ Mathematical 35 ]$$

$${U}_{n} ( s ) = {c}_{n} - {\sum }_{i = 1}^{{m}_{n}} F ( s ; {k}_{n , i} , {μ}_{n , i} , {σ}_{n , i} ) = {c}_{n} - {\sum }_{i = 1}^{{m}_{n}} \frac{{k}_{n , i}}{1 + exp ( - \frac{s - {μ}_{n , i}}{{σ}_{n , i}} )} \qquad ( 35 )$$

Here, cₙ is a constant term. The differential potential function of the negative electrode is represented. by expression (36) obtained through differentiation of the above expression with respect to s.

$$[ Mathematical 36 ]$$

$$\frac{{dU}_{n} ( s )}{ds} = - {\sum }_{i = 1}^{{m}_{n}} \frac{{k}_{n , i} exp ( - \frac{s - {μ}_{n , i}}{{σ}_{n , i}} )}{{( 1 + exp ( - \frac{s - {μ}_{n , i}}{{σ}_{n , i}} ) )}^{2}} \qquad ( 36 )$$

Therefore, the voltage function of the storage battery is represented by expression (37) below, from expression (33) and expression (35).

$$[ Mathematical 37 ]$$

$$U ( s ) = c + bs + {k}_{0} ( s + {σ}_{0} log ( 1 + exp ( - \frac{s - {μ}_{0}}{{σ}_{0}} ) ) ) + {\sum }_{i = 1}^{m} \frac{{k}_{i}}{1 + exp ( - \frac{s - {μ}_{i}}{{σ}_{i}} )} \qquad ( 37 )$$

Here, c=cₚ−cₙ.

The differential voltage function of the storage battery is represented by expression (35) below, from expression (34) and expression (36).

$$[ Mathematical 38 ]$$

$$\frac{dU ( s )}{ds} = b + \frac{{k}_{0}}{1 + exp ( - \frac{s - {μ}_{0}}{{σ}_{0}} )} + {\sum }_{i = 1}^{m} \frac{{k}_{i} exp ( - \frac{s - {μ}_{i}}{{σ}_{i}} )}{{( 1 + exp ( - \frac{s - {μ}_{i}}{{σ}_{i}} ) )}^{2}} \qquad ( 38 )$$

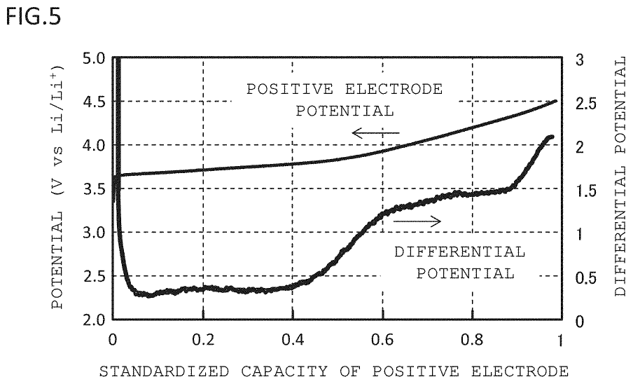

FIG. 5 is a characteristic diagram showing an example of the potential curve and. the differential potential curve of the positive electrode in a lithium ion battery having an MC-based positive electrode and a graphite negative electrode, In. FIG. 5, the horizontal axis represents standardized capacity of the positive electrode, and the vertical axis represents potential. The left vertical axis represents positive electrode potential and the right vertical axis represents differential potential. Actual storage batteries are not usually used when the standardized capacity of the positive electrode is near 0 and near 1. As seen from FIG. 5, the potential curve of the positive electrode has a gentle shape. Therefore, it is considered that the potential curve of the positive electrode represents the shape well when a constant term, a linear term, a sigmoid-type function, and the like are used in addition to an element peak function. This is why the example of the positive electrode potential function shown in expression (33) includes the constant term, the linear term, and the integration term of the logistic function.

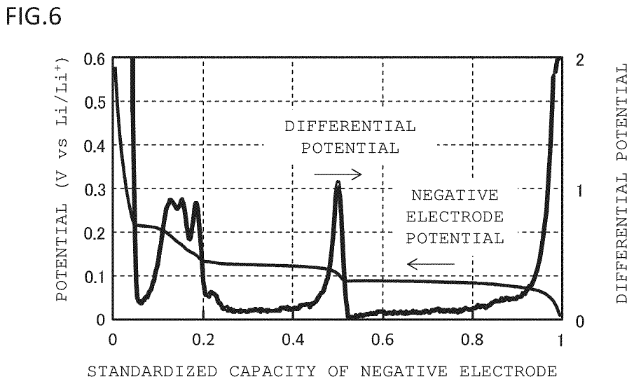

FIG. 6 is a characteristic diagram showing an example of the potential curve and the differential potential curve of the negative electrode in the same lithium ion battery. In FIG. 6, the horizontal axis represents standardized capacity of the negative electrode and the vertical axis represents potential. The left vertical axis represents negative electrode potential and the right vertical axis represents differential potential. Actual storage batteries are not usually used when the standardized capacity of the negative electrode is near 1. When compared with the potential curve of the positive electrode shown in FIG. 5, the potential curve of the negative electrode has flat regions and step-like regions. Therefore, the differential potential curve indicates sharper peak superposition. Thus, it is considered that the differential potential curve of the negative electrode can represent the shape well in terms of the sum of element peak functions represented by expression (36).

Without knowing in advance the differential voltage curves of the positive electrode and the negative electrode regarding the storage battery to be diagnosed as shown in FIG. 5 and FIG. 6, the storage battery state estimation device of the present embodiment estimates a model function from the differential voltage curve of a measured storage battery, and further separates the model function into a positive electrode model function and a negative electrode model function, to perform estimation thereof, Problems at this time are the following three points.

<Problem 1: Problem of Parameter Estimation>

One element function usually has three parameters. Therefore, in a model function corresponding to a differential voltage curve having a large number of peaks, the number of parameters to he estimated increases in accordance with the number of element functions representing the model function, is a result, difficulty in estimation increases in association with increase in the number of parameters.

<Problem 2: Problem of Peak Detection>

In order to perform estimation of a function and estimation of parameters of the function, it is necessary to perform peak detection from differential voltage curve and assign an element peak function to each peak. In this case, the error in the measurement values of current and voltage is amplified in differential operation at the time of calculation of the differential voltage, and thus, there is a risk of erroneous detection. In addition, there may be cases where a peak to be detected does not have a local maximum value, and thus, there is also a risk of non-detection. Further, since the shape of peak becomes gentle due to the deterioration state of the storage battery, the charge condition, the environment of the storage battery, and the like, peak detection becomes difficult. For example, in a case where a storage battery has deteriorated, if a large current flows, distribution of the lithium ion concentration is likely to occur between layers in the electrode, in such a case where the temperature is low. Due to the lithium ion concentration distribution, distribution occurs in the electrode potential. As a result, the shape of the voltage curve of the cell voltage being the average value of the distribution of the electrode potential becomes gentle.

<Problem 3: Problem of Separation of Positive Electrode Model Function and Negative Electrode Model Function>

Even in a case of the sane material-based lithium ion battery, if the type is different, there is a possibility that the number of peaks, the shape, and the like of the differential potential curve are different. In addition, the peak shape of the differential potential curve will also change in accordance with advancement of deterioration. It is not easy to accurately separate the differential potential curve into a positive electrode differential potential curve and a negative electrode differential potential perform estimation thereof.

In the following, a solution for the above-described three problems with respect to the storage battery state estimation device of the present embodiment is described.

<Countermeasure to Problem 1>

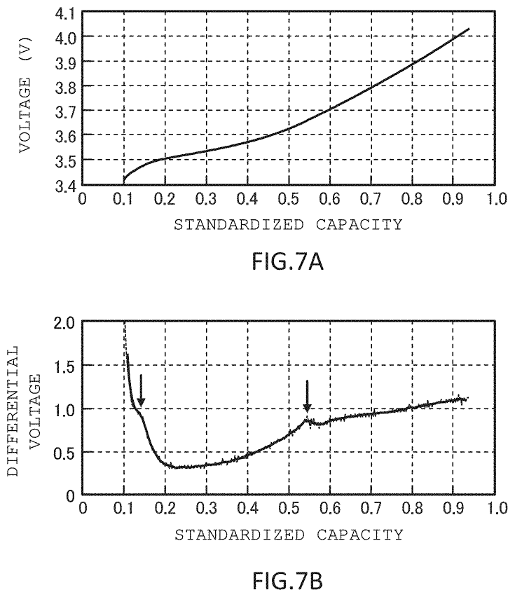

FIG. 7 shows characteristic diagrams showing a voltage curve and a differential voltage curve of a lithium ion battery. In FIG. 7, the horizontal axis represents standardized capacity. FIG. 7A shows the voltage curve and FIG. 7B shows the differential voltage curve. In FIG. 7B, a broken line indicates the measured value, and a solid line indicates the value having been subjected to smoothing processing. Further, in FIG. 7B, the positions of peaks to be detected in the differential voltage curve are indicated by arrows. As shown in FIG. 7B, the measured value of the differential voltage includes noise. Further, it is seen that the peak to be detected in a region where the standardized capacity is small does not have a local maximum value.

The baseline function estimation unit 31 of the present embodiment considers that “differential voltage curve=peak curve+baseline curve”, a peak curve by subtracting a baseline curve. Therefore, peak detection can be facilitated by extracting only the peaks to be detected. The baseline curve is calculated on the basis of a convex hull, for example. The convex hull means a minimum convex polygon that includes all given points. The baseline curve, i.e., a lower hull, is obtained by connecting counterclockwise the points at the left end and the right end in a convex hull calculated from all data points of a differential voltage curve in an estimation range. The baseline function estimation unit 31 estimates a baseline function with respect to the baseline curve. Then, the baseline function estimation unit 31 estimates the optimum parameter, of the baseline function, that minimizes the error between the estimated baseline function and the baseline curve.

Next, the peak function. estimation unit 32 of the present embodiment applies a general peak detection technique to the peak curve calculated by subtracting the baseline curve from the differential voltage curve. Then, using information of each detected peak, such as, for example, information of the height of the peak, the position of the peak, and the width of the peak, the peak function estimation unit 32 estimates a peak function corresponding to the detected peak. Information of the detected peak can be used as an initial parameter of the parameter of the peak function to be estimated.

Next, the model function estimation unit 33 of the present embodiment sets, as a model function, the function represented by the sum of the baseline function and the peak function. In addition, using the optimum parameter of the baseline function and the optimum parameter of the peak function as initial parameters, the model function estimation unit 33 estimates the optimum parameter, of the model function, that minimizes the error between the data point sequence and the model function. Further, the model function estimation unit 33 generates an error point sequence that has the error between the data point sequence and the model function as an element.

Next, the error peak detection unit 34 of the present embodiment applies peak detection to the error point sequence, and when any error peak has been detected, performs estimation of an error peak function with respect to the detected error peak. Further, the error peak detection unit 34 estimates the optimum parameter of the error peak. function.

Further, the model function estimation unit 33 re-estimates the model function by using the error peak function. That is, the model function estimation unit 33 sets, as a new model function, the model function estimated last time to which the error peak function is added. Using, as initial parameters, the optimum parameter of the model function estimated last time and the optimum parameter of the error peak function, the model function estimation unit 33 estimates the optimum parameter, of the model function, that minimizes the error between the new model function and the data point sequence. Further, the model function estimation unit 33 regenerates the error point sequence that has the error between the data point sequence and the new model function as an element. A loop of such model function estimation, peak detection with respect to the error point sequence, and estimation of the error peak function is repeated.

Lastly, the function generation unit 3 ends the process at the time point when no more error peak is detected from the error point sequence in the error peak detection. unit 34, and sets the newest model function at that time as the model function that has been eventually estimated.

In the storage battery state estimation device of the present embodiment, the data point sequence of the differential voltage is separated into a baseline point sequence and a peak point sequence in the baseline function estimation unit 31. Therefore, the model function to be estimated is divided into two functions of the baseline function and the beak function. Thus, the number of parameters to be estimated at one time is reduced. As a result, estimation of parameters in the baseline function estimation unit 31 and the peak function estimation unit 32 is facilitated. In addition, the model function estimation unit 33 estimates a parameter of the model function, using the optimum parameter of the baseline function and the optimum parameter of the peak function as initial parameters. Further, the model function estimation unit 33 estimates a parameter of the new model function, using the optimum parameter of the model function estimated last time and the optimum parameter of the error peak function as initial parameters. As a result, the difficulty in estimation of parameters in the model function estimation unit 33 is reduced.

As described above, the storage battery state estimation device of the present embodiment solves the above-described problem 1 by dividing the model function to be estimated into two functions of a baseline function and a peak function, and by performing estimation of parameters of the model function, using the two optimum parameters as initial parameters.

<Countermeasure to Problem 2>

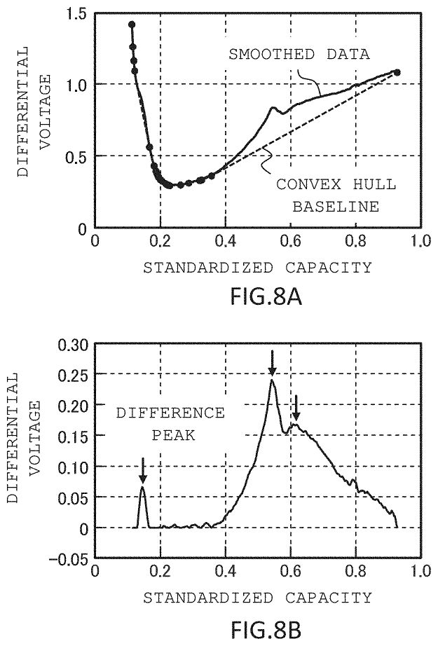

FIG. 3 is characteristic diagrams showing a differential voltage curve and a difference peak of a lithium ion battery. In FIG. 8, the horizontal axis represents standardized capacity. FIG. 8A shows a differential voltage having been subjected to smoothing processing and a calculated convex hull baseline. FIG. 8B shows a difference peak of the differential voltage calculated by subtracting the convex hull baseline from the differential voltage. In FIG. 8A, a solid line indicates the differential voltage having been subjected to smoothing processing, and a broken line indicates the convex hull baseline. In FIG. 8B, three arrows at the difference peak indicate peak positions detected when a general peak detection technique has been applied. As seen from FIG. 8A, the convex hull baseline extends as if supporting the lower side of the differential voltage. Therefore, it seen that, in the difference peak obtained by subtracting the convex hull baseline from the differential voltage, peaks included in the differential voltage become clearer as shown in FIG. 8B. According to this method, the peak on the left side that has not been detected as a peak because the peak does not have a local maximum value in the differential voltage in FIG. 7B is shown to have a clear local maximum value in the difference peak. As a result, the risk of non-detection is reduced.

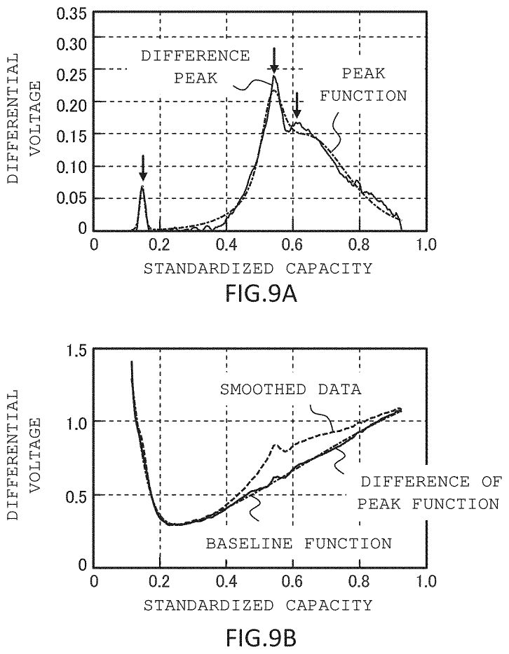

FIG. 9 shows characteristic diagrams showing a difference peak and a differential voltage in the storage battery state estimation device of the present embodiment. In FIG. 9, the horizontal axis represents standardized capacity. FIG. 9A shows the difference peak and an estimated peak function. FIG. 9B shows the differential voltage having been subjected to smoothing processing, the difference between the differential voltage having been subjected to smoothing processing and the estimated peak function, and a baseline function. The baseline function shown in FIG. 9B is a result estimated by using the difference between the differential voltage of the actually measured value, and the estimated peak function. In FIG. 9A, a solid line indicates the difference peak, and a broken line indicates the estimated peak function. In FIG. 9B, a broken line indicates the differential voltage having been subjected to smoothing processing, an alternate long and short dashed line indicates the baseline function, and a solid line indicates the difference between the differential voltage of the actually measured value and the estimated peak function. In FIG. 9A, three arrows at the difference peak show the peak. positions detected when a general peak detection technique has been applied. As seen from FIG. 9B, in the storage battery state estimation device of the present embodiment, a result in which the error between the estimated baseline function and the difference between the differential voltage having been subjected to smoothing processing and the estimated peak function is small, is obtained.

Here, the baseline function is estimated by using the difference between the differential voltage and the estimated peak function, but the baseline function may be estimated by using a convex hull baseline.

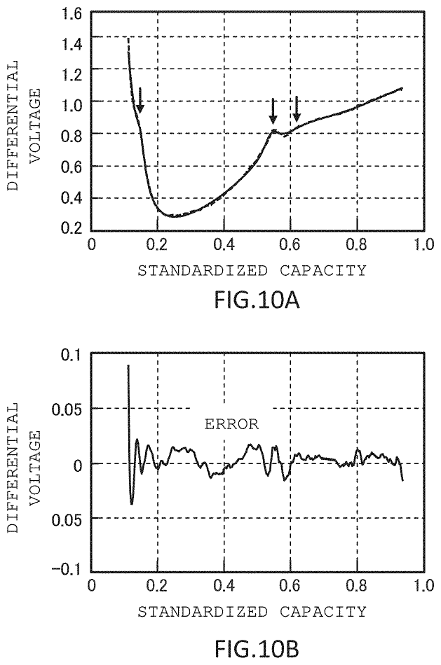

FIG. 10 shows characteristic diagrams showing an estimation result of the differential voltage of the cell by a model function and the error thereof in the storage battery state estimation device of the present embodiment. In FIG. 10, the horizontal axis represents standardized capacity. FIG. 10A shows the actually measured value of differential voltage, and the calculated value of differential voltage calculated from the estimated model function. FIG. 10B show the error between the actually measured value and the calculated value of differential voltage. In FIG. 10A, a solid line indicates the calculated value of differential voltage, and a broken line indicates the actually measured value of differential voltage. Here, arrows in FIG. 10A indicate the peak positions of three element peak functions that have eventually been estimated. As shown in FIG. 10, it is seen that, in the storage battery state estimation device of the present embodiment, the actually measured value and the calculated value according to the model function match each other well. In this example, since the error between the actually measured value and the calculated value of differential voltage is small, no error peak is detected in peak detection with respect to the error point sequence in the error peak detection unit 34, and the model function configured at first is used as is, as the final model function.

It should be noted. that, even in a case where an end point of the error has a local maximum value as shown in FIG. 10B, the end point is not detected as an error peak by a general peak detection technique. However, in a case where a general peak detection technique is applied and then, an end point of the error exceeds a threshold determined in advance and has a local maximum value, it becomes possible to detect the end point as an error peak if a process of detecting, etc., the error peak as a peak is added. However, here, for simplification, the end point is not included in the error peak detection target.

As described above, the storage battery state estimation device of the present embodiment solves the above-described problem 2 by performing peak detection using the difference peak obtained by subtracting the baseline function from the differential voltage.

<Countermeasure to Problem 3>

The shape of the differential potential curve of the positive electrode shown in FIG. 5 and the shape of the differential potential curve of the negative electrode shown in FIG. 6 are significantly different from each other. The differential potential curve of the positive electrode has a gentle shape, whereas the differential potential carve of the negative electrode has sharp peaks in a low capacity region and a high capacity region. In addition, the differential potential curve of the positive electrode is gentle in a low capacity region, and the slope thereof increased from a medium capacity region toward a high capacity region. Further, the differential potential curve of negative electrode is sharp in a low capacity region, and becomes gentle from a medium capacity region toward a high capacity region. Therefore, the differential voltage curve of the cell being the difference between the differential potential curve of the positive electrode and the differential potential curve of the negative electrode is predicted to have a minimum point. The minimum point of the differential voltage curve of the cell is predicted to be at a position in a range from a low capacity region the higher capacity side with respect to the position of the sharp peak in a low capacity region in the differential potential curve of the negative electrode, to a medium capacity region. Therefore, in the storage battery state estimation device of the present embodiment, using the minimum point of the differential voltage curve of the cell as a reference position, element peak functions on the lower capacity side with respect to this minimum point, and an element peak function that has the maximum peak among element peak functions on the higher capacity side with respect to the minimum point are caused to be attributed to the negative electrode model function. Then, all of the remaining element peak functions are caused to be attributed to the positive electrode model function.

The above-described method in which the minimum point of the differential voltage curve of the cell is used as a reference position, thereby separating attribution to the positive electrode model function and. attribution to the negative electrode model function, is an example, and another method may be used. For example, in the data point sequence generation unit 2, the function generation unit 3, or the electrode model function estimation unit 4, the positive electrode material and the negative electrode material of the storage battery to be diagnosed may be estimated on the basis of inputted data, and a reference for separating attribution to the positive electrode model function and attribution to the negative electrode model function may be determined on the basis of the estimated materials. Alternatively, without setting in advance a reference for separating attribution to the positive electrode model function and attribution to the negative electrode model function, an optimum reference may be determined by using a technology such as machine Learning, artificial intelligence (AI), or the like.

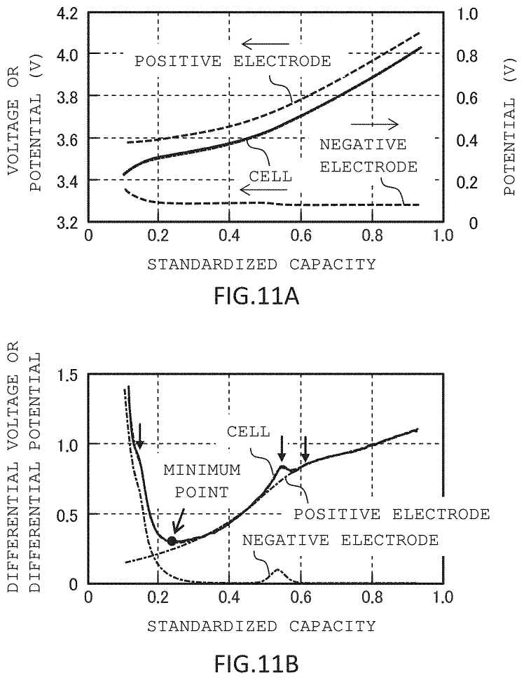

FIG. 11 shows characteristic diagrams showing characteristics estimated by the storage battery state estimation device of the present embodiment with respect to a lithium ion battery. The characteristics shown in FIG. 11 are results calculated by adopting the above-described method of performing separation into a positive electrode model function and a negative electrode model function using the minimum point of the differential voltage curve of the cell as a reference position. In FIG. 11, the horizontal axis represents standardized capacity. FIG. 11A shows the cell voltage, and the positive electrode potential and the negative electrode potential calculated from the estimated positive electrode model function and negative electrode model function. FIG. 11B shows the differential voltage of the cell, and the differential potential of the positive electrode and the differential potential of the negative electrode calculated from the estimated positive electrode model function and negative electrode model function. In FIG. 11, broken lines of the cell voltage and the differential voltage of the cell indicate the values calculated by the estimated model function, and solid lines lo indicate actually measured values. In FIG. 11B, the minimum point of the differential voltage of the cell is shown. In FIG. 11B, peak positions of element peak functions estimated from the differential potential of the negative electrode are indicated by arrows. Since the constant term cₚ of the positive electrode potential function shown in expression (33) and the constant term cₙ of the negative electrode potential function shown in expression (35) cannot be separated in principle, calculation here was performed assuming that cₙ=0.08. cₚ can be calculated by subtracting cₙ from the value of c of the estimated potential function of the cell.

As shown in FIG. 11, in both of the cell voltage and the differential voltage of the cell, the value calculated by the estimated model function and the actually measured value substantially match each other. From this, it can be confirmed that the method of separating attribution the positive electrode model function and attribution to the negative electrode model function by using the minimum point of the differential voltage curve of the cell voltage as a reference position is effective.

As described above, the storage battery state estimation device of the present embodiment solves the above-described problem 3 by separating attribution to the positive electrode model function and attribution to the negative electrode model function by using the minimum point of the differential voltage curve of the cell voltage as a reference position.

Next, a result obtained by applying the storage battery state estimation device of the present embodiment to a lithium ion battery of a different type is described.

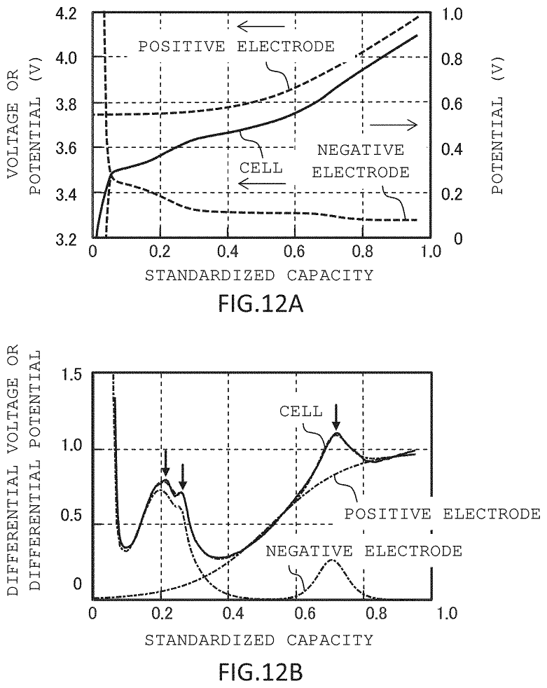

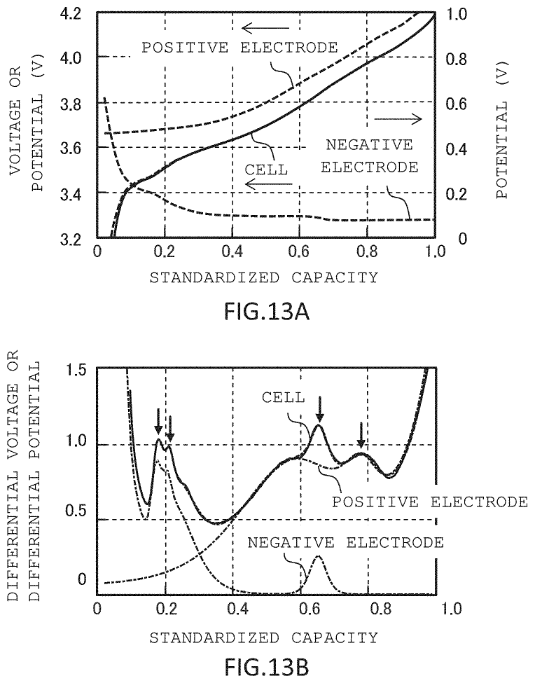

FIG. 12 and FIG. 13 are characteristic diagrams showing characteristics calculated by, with respect to a lithium ion battery of a different type using a ternary material in the positive electrode, separating a model function estimated by the storage battery state estimation device of the present embodiment into a positive electrode model function and a negative electrode model function by the above-described method. In FIG. 12 and FIG. 13, the horizontal axis represents standardized capacity. FIG. 12A and FIG. 13A each show the cell voltage, and the positive electrode potential and the negative electrode potential calculated from the estimated positive electrode model function and negative electrode model function. FIG. 12B and FIG. 13B each show the differential voltage of the cell, and the differential potential of the positive electrode and the differential potential of the negative electrode calculated from the estimated positive electrode model function and negative electrode model function. In FIG. 12 and FIG. 13, broken lines of the cell voltage and the differential voltage of the cell indicate the values calculated by the estimated model function, and solid lines indicate actually measured values.

In FIG. 12B and FIG. 13B, peak positions of element peak functions estimated from the differential voltage of the negative electrode are indicated by arrows. In estimation of the model function with respect to the lithium ion battery shown in FIG. 12 and FIG. 13, thresholds set at the time of peak detection, initial parameters set at the time of estimation of parameters of functions, and the like were used in common.

As shown in FIG. 12 and FIG. 13, in both of the cell voltage and the differential voltage of the cell, the value calculated by the estimated model function and the actually measured value substantially match each other. In particular, in the differential voltage curve of the cell shown in FIG. 13, it is seen that there are two peaks in a region where the standardized capacity is 0.5 to 0.8. It is seen that these two peaks have been accurately estimated although peaks of the differential voltage curve of the negative electrode also exist.

As have been described above, the storage battery state estimation device of the present embodiment can estimate the positive electrode potential, the positive electrode differential potential, the negative electrode potential, and the negative electrode differential potential of the storage battery, without. using the differential potential curves of the positive elect rode and the negative electrode of the storage battery, the voltage curve of the storage battery in the initial state, or the like measure& in advance. As a result, the storage battery state estimation. device of the present embodiment can accurately perform deterioration diagnosis even when there is no characteristic information of the storage battery to be diagnosed.

In the storage battery state estimation device of the present embodiment, the storage battery state is estimated by using the data point sequence composed of the capacity and the differential voltage of the storage battery. Instead of the data point sequence composed of the capacity and the differential voltage of the storage battery, the storage battery state estimation device of the present embodiment may use a data point sequence composed of the voltage of the storage battery and the differential capacity obtained through differentiation of the capacity of the storage battery with respect to voltage.

When the data point sequence composed of the voltage and the differential capacity of the storage battery is used, the model function generated. by the function. generation unit 3 becomes a differential capacity function of the storage battery. Further, the positive electrode model function and the negative electrode model function separated by the electrode model function estimation unit 4 become a differential capacity function of the positive electrode and a differential capacity function of the negative electrode, respectively.

The storage battery state estimation device according to the present embodiment has five advantages as described below.

A first advantage is that estimation of a model function using element functions is facilitated. The baseline function estimation unit separates the data point sequence of the differential voltage of the storage battery into a baseline point sequence and a peak point sequence. Therefore, estimation, by the model function, of the differential voltage curve including a plurality of peaks derived from phase change is facilitated. Specifically, since the data point sequence of the differential voltage is separated into a baseline point sequence and a peak point sequence, the big problem that the data point sequence of the differential voltage is estimated by using one model function is divided into two small problems that the baseline point sequence is estimated in terms of a baseline function, and the peak point sequence is estimated in terms of a peak function. As a result, the peaks to be detected become clear, and peak detection in the peak function estimation unit is facilitated. In addition, since the model function to be estimated is divided into two simple functions of a baseline function and a peak function, the number of element functions for representing each of these two functions is reduced. As a result, the number of parameters to be estimated at one time is reduced, and thus, estimations of parameters in the baseline function estimation unit and the peak function estimation unit are facilitated. Further, in the model function estimation unit, when a parameter of the model function. is to be estimated, an optimum parameter of the baseline function and an optimum parameter of the peak function which are individually estimated can be used as initial parameters. Therefore, the model function estimation. unit can start calculation of a parameter from a value close to an optimum parameter. As a result, estimation of the parameter in the model function estimation unit is more facilitated.

A second advantage is that the baseline point sequence can be assuredly obtained from the data point sequence generated on the basis of the measured value. In separation of the baseline in the baseline function estimation unit, when the point sequence according to data points included in the lower hull of a convex hull of the data point sequence is used as a baseline point sequence, the baseline point. sequence can be assuredly obtained. This is because, as for the algorithm for obtaining a convex hull from a data point sequence, various methods such as Gift wrapping algorithm and Graham scan are known, and the convex hull can be assuredly and efficiently obtained by using these known algorithms.

A third advantage that detection failure of peaks to be detected. can be prevented, and a model function can be highly accurately estimated. In the storage battery state estimation device of the present embodiment, a process in which: the error peak detection unit performs error peak detection and estimation of error peak function with respect to an error point sequence generated by the model function estimation unit; and the model function estimation unit adds the error peak function estimated. by the error peak detection unit and estimates again the model function, is repeated. As a result, the storage battery state estimation device of the present embodiment can prevent detection failure of peaks to be detected, and can highly accurately derive the model function.

There is another advantage that a highly accurate model function can be obtained. For example, it is assumed that a user uses an application of performing conversion to an SOC characteristic, using an OCV characteristic of the storage battery. At this time, when the accuracy of the model function of the differential voltage derived in the storage battery state estimation device of the present embodiment is higher, conversion to a more accurate SOC characteristic can be realized accordingly.

A fourth advantage is that the model function can be highly accurately separated into a positive electrode model function and a negative electrode model function, to perform estimation thereof. The electrode model function estimation unit separates attribution to the positive electrode model function and attribution to the negative electrode model function, by using the minimum point of the differential voltage curve of the cell voltage as a reference position, for example. As a result, in a lithium ion battery using graphite in the negative electrode, even when a different positive electrode material is used, a positive electrode model function and a negative electrode model function can be accurately estimated.

A fifth advantage is that detailed deterioration diagnosis can be performed. For example, with respect to the same storage batteries, if the positive electrode model function and the negative electrode model function estimated in the initial state are compared with the positive electrode model function and the negative electrode model function estimated after use, it becomes possible to perform individual diagnosis of the positive electrode deterioration degree, the negative electrode deterioration degree, and the deterioration degree due to shift in the positional relationship between the positive electrode potential curve and the negative electrode potential curve. In addition, with respect to a plurality of storage batteries having the same specifications, if a plurality of positive electrode model functions and negative electrode model functions that have been estimated are compared with each other, variation and the like of the deterioration of the storage batteries having the same specifications can be diagnosed.

In a conventional deterioration diagnosis method using a general polynomial approximation function or the like, a peak of differential voltage derived from phase change unique to an electrode cannot be represented by the sum of independent functions. Therefore, in the conventional deterioration diagnosis method using a polynomial approximation function or the like, it is impossible to perform separation into a positive electrode model function and a negative electrode model function. In the storage battery state estimation device of the present embodiment, function estimation is performed with respect to the differential voltage on the basis of element functions, and thus, separation into a positive electrode model function. and a negative electrode model function is possible.

The function generation unit of the present embodiment generates a model function that corresponds to a data point sequence configured by a plurality of one-dimensional data x and one-dimensional data y corresponding to each of the one-dimensional data x shown in expression (2). This function generation unit can also generate a model function with respect to a data point sequence in which is of 2 dimensions or higher. For example, when M and N are arbitrary natural numbers, it is also possible to generate a model function that corresponds to M data point sequence {(x₁₁, . . . , x_{1N}, y₁), . . . , (x_{M1}, . . . , x_{MN}, yₙ)} in an N+1-dimensional space configured on the basis of a set x of M N-dimensional data={(x₁₁, . . . , x_{1N}), . . . , (x_{M1}, . . . , x_{MN})} and a set y of one-dimensional data={y₁, . . . , y_{N}}. The function generation unit can generate a model function by separating an N+1-dimensional data point sequence into an N+1-dimensional baseline point sequence and an N+1-dimensional peak point sequence.

That is, the function generation unit of the present embodiment includes: a baseline function estimation unit for separating, when N is a natural number, each of a plurality of data point sequences in an N+1-dimensional space configured by a plurality of N-dimensional data and one-dimensional data corresponding to each of the plurality of N-dimensional data, into a baseline point sequence and a peak point sequence, the baseline function estimation unit being for estimating a baseline function on the basis of the baseline point sequence, and estimating a parameter, of the baseline function, that minimizes an error between the baseline point sequence and the baseline function; a peak function estimation unit for detecting a peak on the basis of the peak point sequence, estimating a peak function on the basis of the peak point sequence, and estimating a parameter, of the peak function, that minimizes an error between the peak point sequence and the peak function; a model function estimation unit for estimating a model function on the basis of the baseline function, the peak function, the parameter of the baseline function, and the parameter of the peak function, estimating a parameter, of the model function, that minimizes an error between the data point sequence and the model function, and generating an error point sequence including the error between the data point sequence and the model function; and an error peak detection unit for detecting presence or absence of an error peak on the basis of the error point sequence, estimating an error peak function on the basis of the error point sequence when the error peak has been detected, and estimating a parameter, of the error peak function, that minimizes an error between the error point sequence and. the error peak function. When an error peak has been detected by the error peak detection unit, the model function estimation unit estimates the model function and the parameter of the model function again on the basis of the error peak function and the parameter of the error peak function.

The function generation unit configured as above can highly accurately estimate the model function.

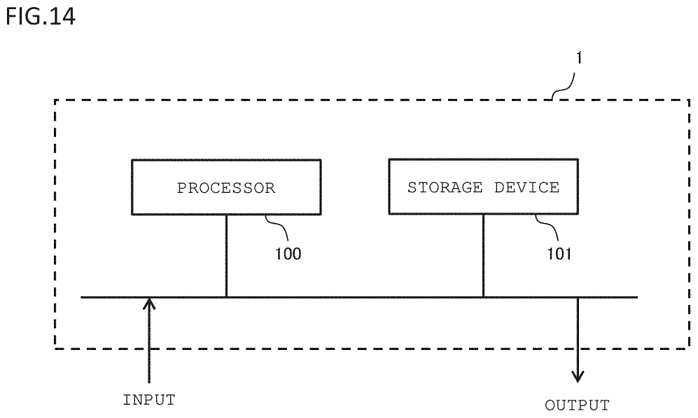

The storage battery state estimation device 1 is implemented by a processor 100 and a storage device 101, as shown in an example of hardware in FIG. 14. The storage device 101 includes, although not shown, a volatile storage device such as a random access memory and a non-volatile auxiliary storage device such as a flash memory. Instead of a flash memory, an auxiliary storage device of a hard disk or the like may be provided. The processor 100 executes a program inputted from the storage device 101. In this case, the program is inputted to the processor 100 from the auxiliary storage device via the volatile storage device. The processor 100 may output data such as a calculation result to the volatile storage device of the storage device 101, or may store data into the auxiliary storage device via the volatile storage device.

Although the present disclosure is described above in terms of an exemplary embodiment, it should be understood that the various features, aspects, and functionality described in. the embodiment are not limited in their applicability to the particular embodiment with which they are described, but instead can be applied alone or in various combinations to the embodiment of the disclosure.

It is therefore understood that numerous modifications which have not been exemplified can be devised without departing from the scope of the present disclosure. For example, at least one of the constituent components may be modified, added, or eliminated.

### DESCRIPTION OF THE REFERENCE CHARACTERS

1 storage battery state estimation device

2 data point sequence generation unit

3 function generation unit

4 electrode model function estimation unit

5 storage battery

6 current detection device

7 voltage detection device

31 baseline function estimation unit

32 peak function estimation unit

33 model function estimation unit

34 error peak detection unit

100 processor

101 storage device

1. A storage battery state estimation device comprising:
data point sequence generation circuitry, on the basis of time-series data of current and voltage of a storage battery, to generate a data point sequence including a capacity of the storage battery and differential voltage obtained through differentiation of the voltage with respect to the capacity, or a data point sequence including the voltage and a differential capacity obtained through differentiation of the capacity with respect to the voltage;
baseline function estimation circuitry to separate the data point sequence into a baseline point sequence and a peak point sequence, estimating a baseline function on the basis of the baseline point sequence, and estimating a parameter, of the baseline function, that minimizes an error between the baseline point sequence and the baseline function;
peak function estimation circuitry to detect a peak on the basis of the peak point sequence, estimating a peak function on the basis of the peak point sequence, and estimating a parameter, of the peak function, that minimizes an error between the peak point sequence and the peak function;
model function estimation circuitry to estimate a model function on the basis of the baseline function, the peak function, the parameter of the baseline function, and the parameter of the peak function, estimating a parameter, of the model function, that minimizes an error between the data point sequence and the model function, and generating an error point sequence including the error between the data point sequence and the model function;
error peak detection circuitry to detect presence or absence of an error peak on the basis of the error point sequence, estimating an error peak function on the basis of the error point sequence when the error peak has been detected, and estimating a parameter, of the error peak function, that minimizes an error between the error point sequence and the error peak function.

2. The storage battery state estimation device according to claim 1, wherein
when the error peak has been detected by the error peak detection circuitry, the model function estimation circuitry estimates again the model function and the parameter of the model function on the basis of the error peak function and the parameter of the error peak function.

3. The storage battery state estimation device according to claim 1, further comprising:
electrode model function estimation circuitry, when the error peak has not been detected by the error peak detection circuitry, to separate the model function into a positive electrode model function and a negative electrode model function, to perform estimation thereof.

4. The storage battery state estimation device according to any one of claim 3, wherein
on the basis of known information regarding the storage battery, the electrode model function estimation circuitry separates the model function into the positive electrode model function and the negative electrode model function, to perform estimation thereof.

5. The storage battery state estimation device according to claim 3, wherein
the model function estimation circuitry estimates the model function as a sum of a plurality of element peak functions, and, by using a minimum point of a differential voltage curve of the storage battery as a reference, the electrode model function estimation circuitry causes the element peak functions on a lower capacity side with respect to the minimum point, and the element peak function that has a maximum peak among the element peak functions on a higher capacity side with respect to the minimum point, to be attributed to the negative electrode model function, and causes all of the remaining element peak functions to be attributed to the positive electrode model function.

6.-7. (canceled)

8. The storage battery state estimation device according to claim 1, wherein
the baseline function estimation circuitry separates the data point sequence into the baseline point sequence and the peak point sequence on the basis of a convex hull of the data point sequence.

9. A storage battery state estimation device comprising:
data point sequence generation circuitry, on the basis of time-series data of current and voltage of a storage battery, to generate a data point sequence including a capacity of the storage battery and differential voltage obtained through differentiation of the voltage with respect to the capacity, or a data point sequence including the voltage and a differential capacity obtained through differentiation of the capacity with respect to the voltage;
baseline function estimation circuitry to separate the data point sequence into a baseline point sequence and a peak point sequence, estimating a baseline function on the basis of the baseline point sequence, and estimating a parameter, of the baseline function, that minimizes an error between the baseline point sequence and the baseline function;
peak function estimation circuitry to detect a peak on the basis of the peak point sequence, estimating a peak function on the basis of the peak point sequence, and estimating a parameter, of the peak function, that minimizes an error between the peak point sequence and the peak function;
model function estimation circuitry to estimate a model function on the basis of the baseline function, the peak function, the parameter of the baseline function, and the parameter of the peak function, estimating a parameter, of the model function, that minimizes an error between the data point sequence and the model function, and generating an error point sequence including the error between the data point sequence and the model function;
the baseline function estimation circuitry separates the data point sequence into the baseline point sequence and the peak point sequence on the basis of a convex hull of the data point sequence.

10. A storage battery state estimation method comprising:
a data point sequence generation step of, on the basis of time-series data of current and voltage of a storage battery, generating a data point sequence including a capacity of the storage battery and differential voltage obtained through differentiation of the voltage with respect to the capacity, or a data point sequence including the voltage and a differential capacity obtained through differentiation of the capacity with respect to the voltage;
a baseline function estimation step of separating the data point sequence into a baseline point sequence and a peak point sequence, estimating a baseline function on the basis of the baseline point sequence, and estimating a parameter, of the baseline function, that minimizes an error between the baseline point sequence and the baseline function;
a peak function estimation step of detecting a peak on the basis of the peak point sequence, estimating a peak function on the basis of the peak point sequence, and estimating a parameter, of the peak function, that minimizes an error between the peak point sequence and the peak function;
a model function estimation step of estimating a model function on the basis of the baseline function, the peak function, the parameter of the baseline function, and the parameter of the peak function, estimating a parameter, of the model function, that minimizes an error between the data point sequence and the model function, and generating an error point sequence including the error between the data point sequence and the model function;
an error peak detection step of detecting presence or absence of an error peak on the basis of the error point sequence, estimating an error peak function on the basis of the error point sequence when the error peak has been detected, and estimating a parameter, of the error peak function, that minimizes an error between the error point sequence and the error peak function.

11. The storage battery state estimation method according to claim 10, wherein
an electrode model function estimation step of, when the error peak has not been detected in the error peak detection step, separating the model function into a positive electrode model function and a negative electrode model function, to perform estimation thereof.

12. The storage battery state estimation method according to claim 10, wherein
in the model function estimation step, when the error peak has been detected in the error peak detection step, the model function and the parameter of the model function are estimated again on the basis of the error peak function and the parameter of the error peak function.
